(19) United States
(12) Patent Application Publication
(10) Pub. No.: US 2023/0207325 A1
(43) Pub. Date: Jun. 29, 2023

(54) SEMICONDUCTOR DEVICE MANUFACTURING METHOD

(71) Applicant: FUJI ELECTRIC CO., LTD., Kanagawa (JP)

(72) Inventor: Michiya KITANO, Matsumoto-city (JP)

(21) Appl. No.: 18/175,535

(22) Filed: Feb. 27, 2023

Related U.S. Application Data
(63) Continuation of application No. PCT/JP2022/003409, filed on Jan. 28, 2022.

(30) Foreign Application Priority Data
Mar. 17, 2021 (JP) 2021-044168

(51) Int. Cl. H01L 21/304; H01L 21/683; B24B 7/22

(52) U.S. Cl. CPC H01L 21/304; H01L 21/6836; B24B 7/228

(57) ABSTRACT

To provide a manufacturing method of a semiconductor device including a semiconductor substrate, the manufacturing method of the semiconductor device including a sticking for sticking a protection tape to a first surface of the semiconductor substrate, a first grinding for supporting the protection tape and grinding a second surface of the semiconductor substrate that is a surface on the opposite side of the first surface, a protection tape cutting for supporting the second surface of the semiconductor substrate and flattening the protection tape, and a second grinding for supporting the protection tape and grinding the second surface of the semiconductor substrate. In the second grinding, in order to leave a convex part in an outer circumference of the semiconductor substrate, an inside of the convex part may be ground.

The contents of the following Japanese patent application(s) are incorporated herein by reference:
NO. 2021-044168 filed in JP on Mar. 17, 2021
NO. PCT/JP2022/003409 filed in WO on Jan. 28, 2022

### TECHNICAL FIELD

The present invention relates to a manufacturing method of a semiconductor device.

### BACKGROUND

Conventionally, in grinding methods of a semiconductor substrate, a technique of “cutting the entire front surface of a base film of a protection tape adhered to a front surface of a wafer (substrate) with a cutting tool in a range that does not reach an adhesive layer”, and then “retaining the front surface of the wafer to which the protection tape is adhered, with a chuck table of a grinding device via the protection tape” has been known (for example, refer to Patent Document 1). In addition, in processing methods of a semiconductor substrate, a technique of “forming a concave part in a region corresponding to a device region among a back surface of a wafer (substrate), and forming a ring-shaped reinforced part including an outer circumferential excessive region on the outer circumferential side of the concave part” has been known (for example, refer to Patent Document 2).

Patent Document 1: Japanese Patent Application Publication No. 2013-21017

Patent Document 2: Japanese Patent Application Publication No. 2007-19461

### BRIEF DESCRIPTION OF THE DRAWINGS

FIG. 1 illustrates an example of a manufacturing method of a semiconductor device 100.

FIG. 2 illustrates an example of a sticking S101.

FIG. 3A illustrates the semiconductor device 100 before grinding, in a first grinding S102.

FIG. 3B illustrates the semiconductor device 100 after grinding, in the first grinding S102.

FIG. 4 shows an example of a relationship between a grinding depth and a Total Thickness Variation (TTV) in the first grinding S102.

FIG. 5A illustrates a protection tape 20 in the middle of flattening, in a protection tape cutting S103.

FIG. 5B illustrates the protection tape 20 after flattening, in the protection tape cutting S103.

FIG. 6 illustrates an example of a table processing S104.

FIG. 7A illustrates the semiconductor device 100 before grinding, in a second grinding S105.

FIG. 7B illustrates the semiconductor device 100 after grinding, in the second grinding S105.

FIG. 8A illustrates the semiconductor device 100 before grinding, in the second grinding S105.

FIG. 8B illustrates the semiconductor device 100 after grinding, in the second grinding S105.

FIG. 9A illustrates the semiconductor device 100 before grinding, in the first grinding S102.

FIG. 9B illustrates the semiconductor device 100 after grinding, in the first grinding S102.

FIG. 10A illustrates the semiconductor device 100 before grinding, in the second grinding S105.

FIG. 10B illustrates the semiconductor device 100 after grinding, in the second grinding S105.

FIG. 11 illustrates another example of a manufacturing method of the semiconductor device 100.

FIG. 12 illustrates an example of an estimating S204.

FIG. 13 illustrates a comparative example of the manufacturing method of the semiconductor device 100.

FIG. 14 illustrates an example of a sticking S301.

FIG. 15A illustrates the protection tape 20 in the middle of flattening, in a protection tape cutting S302.

FIG. 15B illustrates the protection tape 20 after flattening, in the protection tape cutting S302.

FIG. 16A illustrates the semiconductor device 100 before attachment to a table 140, in a substrate grinding S303.

FIG. 16B illustrates the semiconductor device 100 after attachment to the table 140, in the substrate grinding S303.

FIG. 16C illustrates the semiconductor device 100 after grinding, in the substrate grinding S303.

FIG. 17 illustrates a forward inclination angle θ1.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention. It should be noted that, in the present specification and drawings, elements having substantially the same functions and configurations are denoted with the same reference signs, and the overlapping descriptions thereof are omitted. In addition, the elements that are not directly relevant to the present invention are not shown. In one drawing, elements having the same function and configuration are representatively denoted by a reference sign, and the reference signs for the others may be omitted.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. The ‘upper’ and ‘lower’ directions are not limited to a gravity direction or a direction at a time of mounting a semiconductor module.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing the signs, it means that the direction is parallel to the +Z axis and the −Z axis. As used herein, the orthogonal axes parallel to an upper surface and a lower surface of the semiconductor substrate are defined as the X axis and the Y axis. In addition, the axis perpendicular to the upper surface and the lower surface of the semiconductor substrate is defined as the Z axis. As used herein, the direction of the Z axis may be referred to as the depth direction. In addition, as used herein, a direction parallel to the upper surface and the lower surface of the semiconductor substrate, including the X axis and the Y axis, may be referred to as a horizontal direction.

As used herein, a case where a term such as “same” or “equal” is mentioned may include a case where an error due to a variation in manufacturing or the like is included. The error is, for example, within 10%.

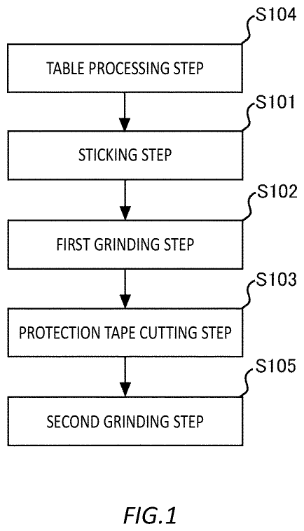

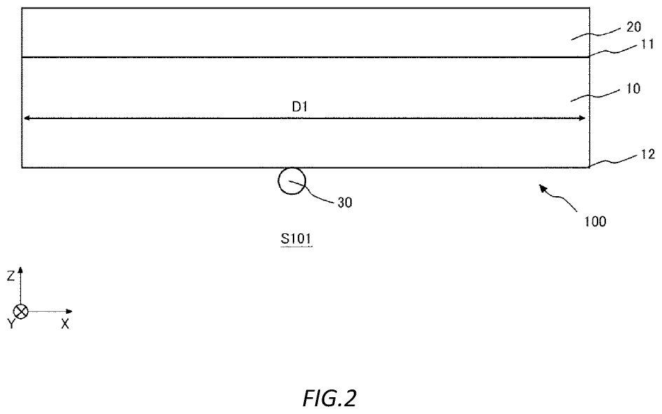

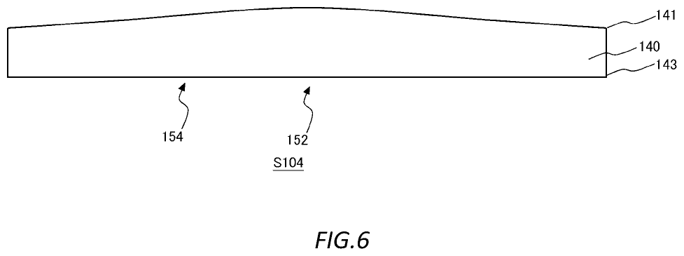

FIG. 1 illustrates an example of a manufacturing method of a semiconductor device 100. The manufacturing method of the semiconductor device 100 includes a table processing S104, a sticking S101, a first grinding S102, a protection tape cutting S103, and a second grinding S105. In the table processing S104, a table used in the second grinding S105 is processed. Hereinafter, each step will be described in FIG. 2 to FIG. 7B. It should be noted that details of the table processing 5104 will be described later in FIG. 6.

It should be noted that, as an example, the semiconductor device 100 functions as a power conversion device such as an inverter. The semiconductor device 100 may include a diode such as an insulated gate bipolar transistor (IGBT), FWD (Free Wheel Diode) and RC (Reverse Conducting)—IGBT provided by combining the two, and a MOS transistor or the like. Also, the semiconductor device 100, as an example, functions as a pressure sensor. The semiconductor device 100 may not be limited to these examples.

FIG. 2 illustrates an example of the sticking S101. The semiconductor device 100 includes a semiconductor substrate 10. In the present example, the semiconductor substrate 10 is a substantially circular wafer, as seen from above. In the present specification, processes except for a process for grinding the semiconductor substrate 10 are omitted. The manufacturing method of the semiconductor device 100 may include: a process for implanting an impurity to a predetermined region of the semiconductor substrate 10; a process for annealing the semiconductor substrate 10; and a process for forming an insulating film, electrode or wiring or the like on a front surface of the semiconductor substrate 10. By those processes, a semiconductor device such as a transistor is formed on the semiconductor substrate 10. The semiconductor substrate 10 is a substrate formed of a semiconductor material. Although the semiconductor substrate 10 is a silicon substrate by way of example, the material of the semiconductor substrate 10 is not limited to silicon. As a diameter D1 of the semiconductor substrate 10, 200±5 mm or 300±5 mm is frequently used as an example. However, it is not limited to this value.

In the sticking S101, a protection tape 20 is stuck to a first surface 11 of the semiconductor substrate 10. The first surface 11 of the semiconductor substrate 10 may be a surface on which a gate structure such as an IGBT or a MOS transistor is formed. The gate structure is, for example, a structure including at least one of a gate electrode, a gate insulating film, a source region, an emitter region, and a channel region. In the sticking S101, the gate structure may be already formed, or may yet to be formed, on the first surface 11. The first surface 11 of the semiconductor substrate 10 may be a so-called device surface. By sticking the protection tape 20 to the first surface 11 of the semiconductor substrate 10, the first surface 11 of the semiconductor substrate 10 can be protected.

The protection tape 20 is a tape for protecting the first surface 11 of the semiconductor substrate 10. Specifically, by sticking the protection tape 20, when grinding a second surface 12 of the semiconductor substrate 10 in the first grinding S102 and the second grinding S105, the first surface 11 of the semiconductor substrate 10 can be prevented from directly contacting a table of a grinding device. The protection tape 20 may be a tape having adhesion. For example, a UV tape or a pressure sensitive tape is generally used for the protection tape 20. However, other than these, an organic coating film as represented by a resist, an attachment sheet by an electrostatic force, a support disc to which an adhesive agent is applied, or the like also can be used. The second surface 12 of the semiconductor substrate 10 is a surface on the opposite side of the first surface 11 of the semiconductor substrate 10.

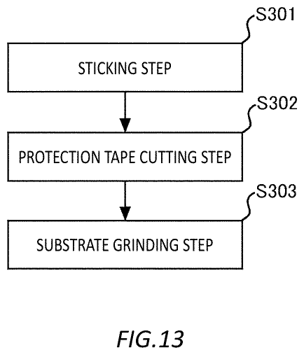

After sticking the protection tape 20, the protection tape 20 is preferably cut to flatten the protection tape 20. In this case, the second surface 12 of the semiconductor substrate 10 is placed on the table to cut the protection tape 20. However, as shown in FIG. 2, a foreign substance 30 may adhere to the second surface 12 of the semiconductor substrate 10. The foreign substance 30 is a foreign substance that is adhered in the manufacturing process of the semiconductor device 100. The foreign substance 30 may be a particle or the like, or may be an organic matter such as a resist or a residue of an oxide film. If the foreign substance 30 is adhered to the second surface 12 of the semiconductor substrate 10, when flattening the protection tape 20 in the protection tape cutting S103, a problem that the protection tape 20 does not become flat will be caused. This problem will be described later in FIG. 13 to FIG. 16C.

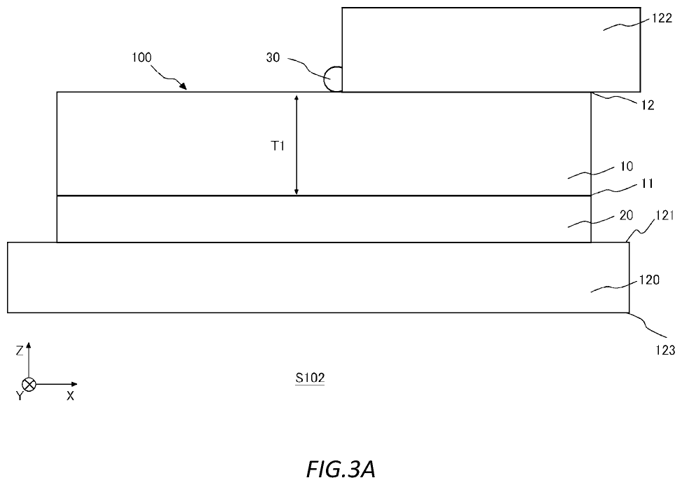

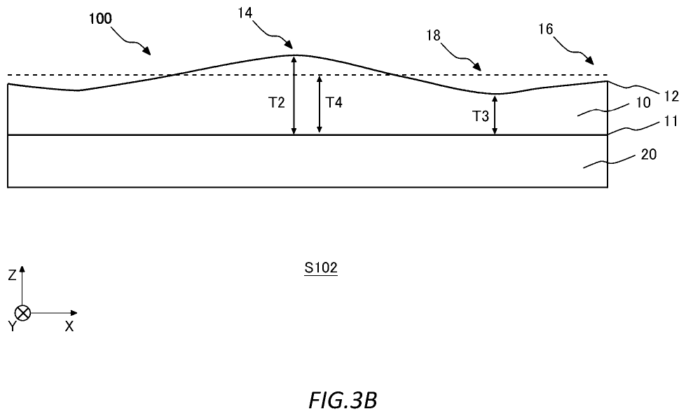

FIG. 3A and FIG. 3B illustrate examples of the first grinding S102. FIG. 3A illustrates the semiconductor device 100 before grinding, in the first grinding S102. FIG. 3B illustrates the semiconductor device 100 after grinding, in the first grinding S102.

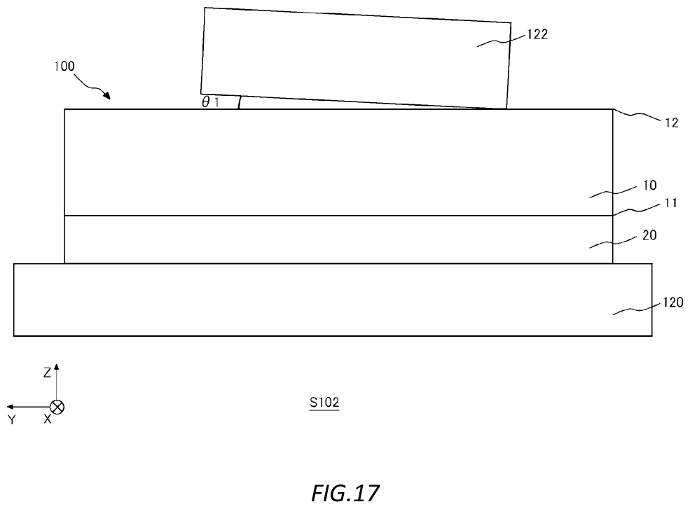

In the first grinding S102, the second surface 12 of the semiconductor substrate 10 is ground. As shown in FIG. 3A, in the first grinding S102, the protection tape 20 is supported by a table 120. In addition, in the first grinding S102, the first surface 11 of the semiconductor substrate 10 is supported by the table 120. In the present example, the first surface 11 of the semiconductor substrate 10 is supported by the table 120 via the protection tape 20. The table 120 may be a chuck table. The table 120 has an upper surface 121 and a lower surface 123. In addition, in the first grinding S102, the second surface 12 of the semiconductor substrate 10 is ground by a whetstone 122. The first grinding S102 is, for example, performed using a grinding device such as a back grinder (BG). By grinding the second surface 12 of the semiconductor substrate 10, the foreign substance 30 can be removed. In the first grinding S102, the second surface 12 may be ground by inclining the whetstone 122 forward. Inclining the whetstone 122 forward refers to inclination of the whetstone 122 with respect to a circumferential direction of the semiconductor substrate 10. In the example of FIG. 3A, the lower surface of the whetstone 122 is arranged to have an inclination (forward inclination angle) with respect to the Y axis direction. The forward inclination angle will be described later in FIG. 17. In addition, in FIG. 3A, an average thickness of the semiconductor substrate 10 is denoted by T1. As used herein, the thickness is a difference between a height of the upper surface and a height of the lower surface in the Z axis direction. In FIG. 3A, the average thickness T1 of the semiconductor substrate 10 is a difference between a height of the second surface 12 and a height of the first surface 11. As used herein, the height is a height from a certain reference. In each figure, the reference may be a portion that is provided on the lowest side in the Z axis direction among each component. In FIG. 3A, the reference is, for example, the lower surface 123 of the table 120. It should be noted that, although the whetstone 122 is described smaller than the semiconductor substrate 10 in FIG. 3A, the diameter of the whetstone 122 may be larger than the diameter of the semiconductor substrate 10.

As shown in FIG. 3B, after the first grinding S102, the semiconductor substrate 10 is processed to have a shape in which a center part 14 becomes convex. It should be noted that, in each figure, concavities and convexities of the semiconductor substrate 10 and the like are exaggeratedly shown. The center part 14 is a portion including the center of the semiconductor substrate 10 in the XY plane. In addition, the semiconductor substrate 10 may have a valley part 18 between the center part 14 and an end part 16. The end part 16 is an end portion of the semiconductor substrate 10 in the X axis and the Y axis. The valley part 18 is a predetermined portion including a portion having a smaller thickness than the center part 14 and the end part 16. In the present example, a thickness T2 of the semiconductor substrate 10 in the center part 14 is the maximum thickness of the semiconductor substrate 10. The thickness T2 of the semiconductor substrate 10 in the center part 14 may be the thickness at the center of the semiconductor substrate 10. In addition, in the present example, a thickness T3 of the semiconductor substrate 10 in the valley part 18 is the minimum thickness of the semiconductor substrate 10. The thickness T3 of the semiconductor substrate 10 in the valley part 18 may be the minimum thickness of the semiconductor substrate 10 in the valley part 18. In addition, in FIG. 3B, the average thickness of the semiconductor substrate 10 is denoted by T4, and is shown with a dotted line.

A grinding depth in the first grinding may be 50 μm or more. The grinding depth in the first grinding may be a difference between the average thickness T1 of the semiconductor substrate 10 in FIG. 3A and the average thickness T4 of the semiconductor substrate 10 in FIG. 3B.

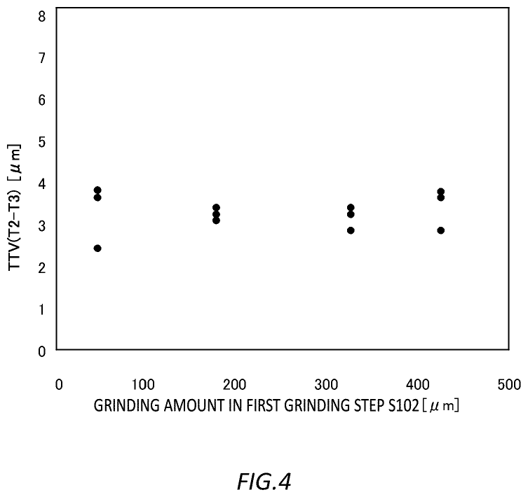

FIG. 4 shows an example of a relationship between the grinding depth in the first grinding S102 and a Total Thickness Variation (TTV). The TTV is a difference between the maximum thickness and the minimum thickness in the semiconductor substrate 10. That is, in the present example, the TTV is a difference between the thickness T2 of the semiconductor substrate 10 in the center part 14 and the thickness T3 of the semiconductor substrate 10 in the valley part 18 in FIG. 3B. In addition, as used herein, an in-plane uniformity represents a processing uniformity of the semiconductor substrate 10. The in-plane uniformity of the semiconductor substrate 10 in FIG. 3B is represented by (T2−T3)/T4, as an example.

Referring to FIG. 4, the TTV is maintained at 2 to 4 μm by setting the grinding depth in the first grinding S102 to 50 μm or more. Accordingly, by setting the grinding depth to 50 μm or more, the TTV after grinding can be maintained approximately constant regardless of the grinding depth. It is considered that the reason why the TTV after grinding can be maintained constant is because the grinding device stably operates by setting the grinding depth to 50 μm or more.

In addition, since the purpose of the first grinding S102 is to remove the foreign substance 30, the grinding depth in the first grinding S102 is preferably not too large. For example, the grinding depth in the first grinding S102 is preferably 200 μm or less. To summarize, the grinding depth in the first grinding S102 may be 50 μm or more and 200 μm or less.

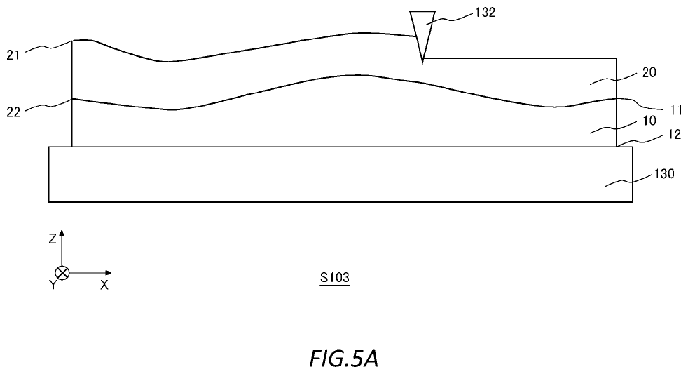

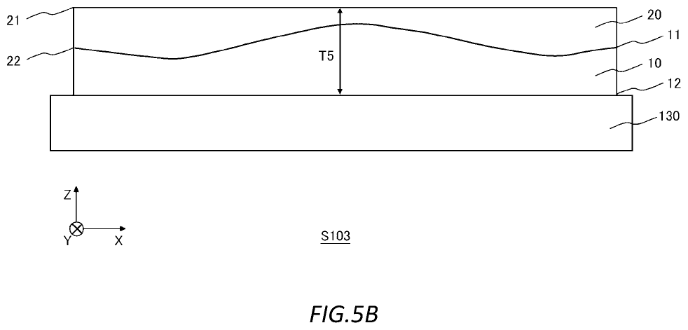

FIG. 5A and FIG. 5B illustrate examples of the protection tape cutting S103. FIG. 5A illustrates the protection tape 20 in the middle of flattening, in the protection tape cutting S103. FIG. 5B illustrates the protection tape 20 after flattening, in the protection tape cutting S103. The protection tape 20 has a first surface 21 and a second surface 22. The second surface 22 is a surface overlapping with (or a surface that contacts) the first surface 11 of the semiconductor substrate 10. The first surface 21 is the surface on the opposite side of the second surface 22.

In the protection tape cutting S103, the protection tape 20 is flattened. In the present example, the first surface 21 of the protection tape 20 is flattened, in the protection tape cutting S103. In the protection tape cutting S103, the second surface 12 of the semiconductor substrate 10 is supported by a table 130. In addition, as shown in FIG. 5A, in the protection tape cutting S103, the second surface 22 of the protection tape 20 is supported by the table 130. In the present example, the second surface 22 of the protection tape 20 is supported by the table 130 via the semiconductor substrate 10. In addition, in the protection tape cutting S103, the first surface 21 of the protection tape 20 is flattened with a flattening tool 132. The flattening tool 132 is, for example, a tool having a blade cutting edge. In the protection tape cutting S103, a front surface of the protection tape 20 may be cut by bringing the blade cutting edge of the flattening tool 132 into contact with the protection tape 20.

In the present example, the manufacturing method of the semiconductor device 100 includes the first grinding S102. Accordingly, the foreign substance 30 adhered to the second surface 12 of the semiconductor substrate 10 can be removed, and as shown in FIG. 5B, a total thickness T5 of the semiconductor substrate 10 and the protection tape 20 can be made constant. In FIG. 5A, the total thickness T5 of the semiconductor substrate 10 and the protection tape 20 is a difference between a height of the first surface 21 of the protection tape 20 and a height of the second surface 12 of the semiconductor substrate 10. As a result, the in-plane uniformity of the semiconductor substrate 10 can be improved as compared to a case in which the first grinding S102 is not included.

FIG. 6 illustrates an example of the table processing S104. In the table processing S104, a table 140 used in the second grinding S105 is processed. The table 140 supports the first surface 11 of the semiconductor substrate 10, in the second grinding S105. The table 140 has an upper surface 141 and a lower surface 143. In the table processing S104, the table 140 used in the second grinding S105 is processed based on an expected shape of the second surface 12 of the semiconductor substrate 10 after the first grinding S102. The expected shape of the second surface 12 of the semiconductor substrate 10 after the first grinding S102 may be a shape that is assumed in advance. That is, it may be a shape of the second surface 12 of the semiconductor substrate 10 after performing the first grinding S102 in the past. As an example, the table 140 is processed based on the TTV of the semiconductor substrate 10 that is expected after the first grinding S102. In addition, the shape of the second surface 12 may be predicted from the diameter of the whetstone 122 and the forward inclination angle of the whetstone 122.

As an example, two portions in the XY plane of the semiconductor substrate 10 are regarded as a first substrate portion and a second substrate portion. In addition, in the table 140 used in the second grinding S105, a portion where the first substrate portion is placed, is regarded as a first table portion, and a portion where the second substrate portion is placed, is regarded as a second table portion. If the first substrate portion of the semiconductor substrate 10 is predicted to be thicker than the second substrate portion, a height of the upper surface 141 of the first table portion may be made higher than the height of the upper surface 141 of the second table portion. In FIG. 6, a portion where the center part 14 of the semiconductor substrate 10 in FIG. 3B is placed, is regarded as a first table portion 152. In addition, in FIG. 6, a portion where the valley part 18 of the semiconductor substrate 10 in FIG. 3B is placed, is regarded as a second table portion 154. The height of the upper surface 141 of the first table portion 152 may be made higher than the height of the upper surface 141 of the second table portion 154. It should be noted that, the height of the upper surface 141 of the table 140 is the height from the lower surface 143 (reference) of the table 140.

In FIG. 4, it was described that the TTV after grinding can be maintained constant by setting the grinding depth in the first grinding S102 to 50 μm or more. Accordingly, if the grinding depth in the first grinding S102 is determined, the expected shape of the second surface 12 of the semiconductor substrate 10 after the first grinding S102 can be determined. Therefore, a processing shape of the table 140 can be determined in advance based on the expected shape of the second surface 12 of the semiconductor substrate 10 after the first grinding S102. Therefore, the table processing S104 can be performed in advance prior to the sticking S101. In addition, when grinding a plurality of the semiconductor substrates 10 in order using the table 140, the table processing S104 may be performed just once before grinding the plurality of semiconductor substrates 10. That is, the sticking S101, the first grinding S102, the protection tape cutting S103, and the second grinding S105 may be performed for each semiconductor substrate 10, and the table processing S104 may be commonly performed for the plurality of semiconductor substrates 10.

The table 140 is, as an example, formed of a ceramic or metal material, and it may be a porous chuck table. The processing of the table 140 may be a general metal processing, or may be a grinding processing that is performed by bringing a whetstone into contact with a table. In the case of the grinding processing, a desired table shape can be obtained by adjusting the forward inclination angle of the whetstone. The whetstone used at this time may be the same as that used for the processing of a semiconductor substrate, or may be a different whetstone. The forward inclination angle will be described later using FIG. 17.

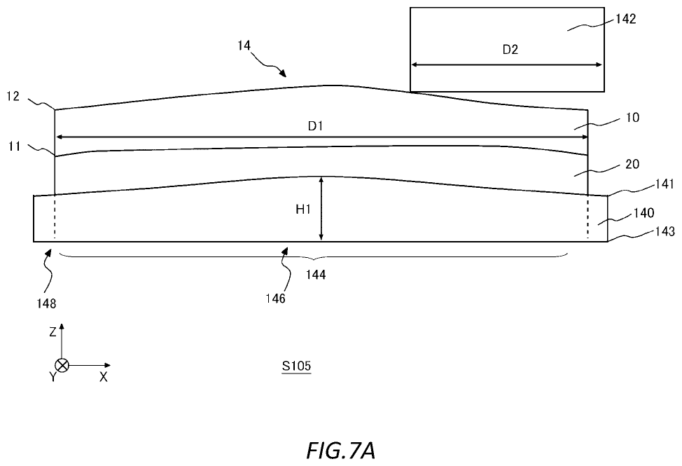

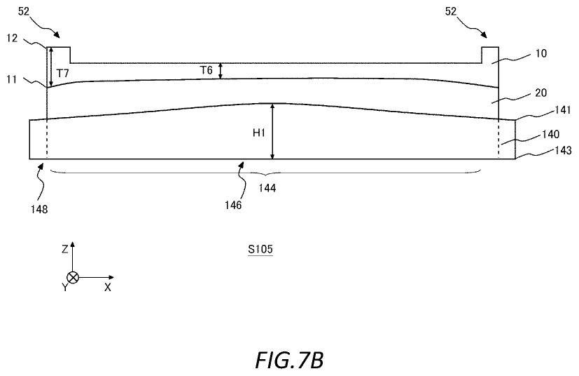

FIG. 7A and FIG. 7B illustrate examples of the second grinding S105. FIG. 7A illustrates the semiconductor device 100 before grinding, in the second grinding S105. FIG. 7B illustrates the semiconductor device 100 after grinding, in the second grinding S105.

In the second grinding S105, the second surface 12 of the semiconductor substrate 10 is ground. In the second grinding S105, the protection tape 20 is supported by the table 140. In addition, as shown in FIG. 7A, in the second grinding S105, the first surface 11 of the semiconductor substrate 10 is supported by the table 140. In the present example, the first surface 11 of the semiconductor substrate 10 is supported by the table 140 via the protection tape 20. The table 140 may be a chuck table. In the table processing S104, the table 140 is processed based on the expected shape of the second surface 12 of the semiconductor substrate 10 after the first grinding S102, and thus the thickness of the semiconductor substrate 10 can be uniformized even if the thickness of the semiconductor substrate 10 is varied. In addition, in the second grinding S105, the second surface 12 of the semiconductor substrate 10 is ground with a whetstone 142. The second grinding S105 is, for example, performed using a grinding device such as a back grinder (BG). In the second grinding S105, the second surface 12 may be ground by inclining the whetstone 142 forward as in the case of the first grinding S102.

As shown in FIG. 7B, after the second grinding S105, the semiconductor substrate 10 is processed to have a constant thickness T6. After the first grinding S102, the semiconductor substrate 10 is processed such that the center part 14 have a convex shape. However, in the present example, the table 140 used in the second grinding S105 is processed based on the shape of the second surface 12 of the semiconductor substrate 10 after the first grinding S102, and thus the semiconductor substrate 10 can be flattened. Accordingly, the in-plane uniformity of the semiconductor substrate 10 can be improved.

In the present example, regarding the table 140, in a portion 144 overlapping with the first surface 11 of the semiconductor substrate 10, the height of the upper surface 141 monotonously decreases from a center part 146 of the portion 144 to an end part 148 of the region. That is, a height H1 of the upper surface 141 of the table 140 in the center part 146 of the portion 144 may be the maximum among the height of the upper surface 141 of the table 140 in the portion 144. In FIG. 7A and FIG. 7B, a boundary between the portion 144 and other portions of the table 140 is shown with a dotted line. The center part 146 of the portion 144 is a portion including the center of the portion 144 in the XY plane. The end part 148 is an end portion of the portion 144 in the X axis or the Y axis. It should be noted that, in the present example, the portion 144 is in contact with the first surface 11 of the semiconductor substrate 10 via the protection tape 20. By allowing the table 140 to have such shape, the center part 14 of the semiconductor substrate 10 can be arranged relatively higher as compared to other portions. Accordingly, the center part 14 of the semiconductor substrate 10 can be largely ground as compared to other portions, and the in-plane uniformity of the semiconductor substrate 10 can be improved.

In the present example, in the second grinding S105, a convex part 52 is formed in the outer circumference of the semiconductor substrate 10. That is, in the second grinding S105, in order to leave the convex part 52 in the outer circumference of the semiconductor substrate 10, an inside of the convex part 52 is ground. By leaving the convex part 52 in the outer circumference, a ring-shaped reinforced structure can be left in the semiconductor substrate 10. Accordingly, a warpage of the semiconductor substrate 10 can be suppressed after the second grinding S105. In addition, in processes after the second grinding S105, handling of the semiconductor substrate 10 is facilitated. To form the convex part 52, an outer diameter D2 of the whetstone 142 is preferably equal to or less than a radius of the semiconductor substrate 10 (half the diameter D1 of the semiconductor substrate 10).

In the present example, the average thickness of the semiconductor substrate 10 excluding the convex part 52 is denoted by T6. In addition, in the present example, the thickness of the semiconductor substrate 10 in the convex part 52 is denoted by T7. T7 may be the maximum thickness of the semiconductor substrate 10 in the convex part 52. The grinding depth in the second grinding S105 may be a difference between T7 and T6. The grinding depth in the second grinding S105 may be 450 μm or more. That is, the grinding depth in the first grinding S102 may be smaller than the grinding depth in the second grinding S105. Accordingly, in the second grinding S105, the semiconductor substrate 10 can be made thin.

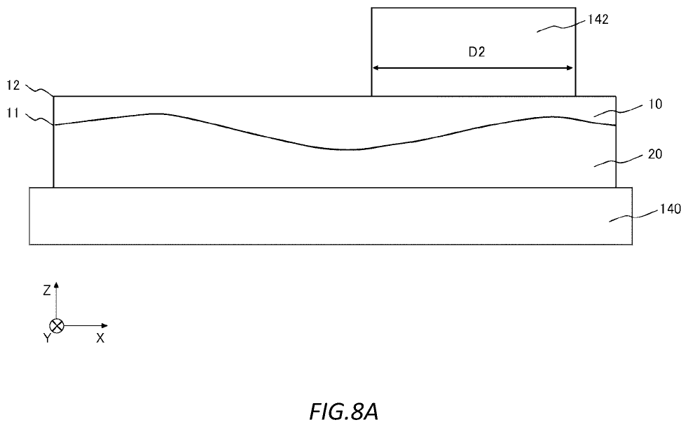

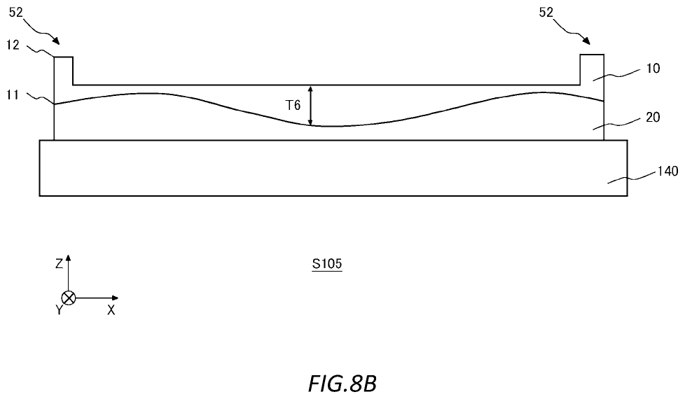

FIG. 8A and FIG. 8B illustrate comparative examples of the second grinding S105. FIG. 8A illustrates the semiconductor device 100 before grinding, in the second grinding S105. FIG. 8B illustrates the semiconductor device 100 after grinding, in the second grinding S105. In FIG. 8A and FIG. 8B, the shape of the table 140 is changed from FIG. 7A and FIG. 7B. The shape of the table 140 in FIG. 8A and FIG. 8B is flat, unlike in FIG. 7A and FIG. 7B.

In FIG. 8B, after the second grinding S105, the thickness T6 of the semiconductor substrate 10 is not uniform. This is because the shape of the semiconductor substrate 10 formed after the first grinding S102 is remained in the second grinding S105. By processing the table 140 used in the second grinding S105, the shape of the semiconductor substrate 10 formed after the first grinding S102 can be flattened.

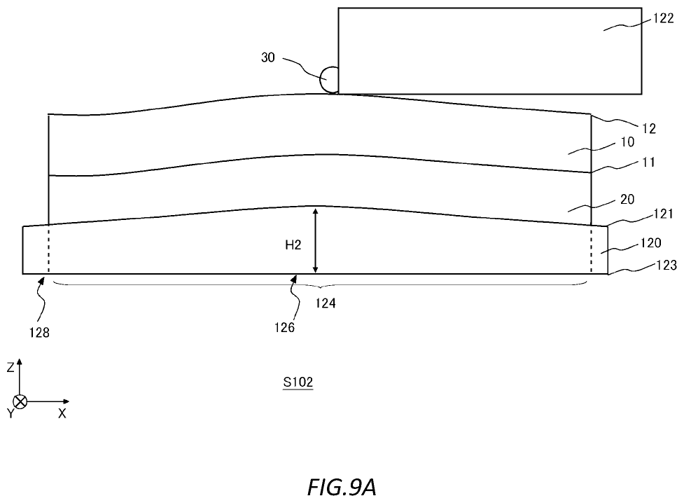

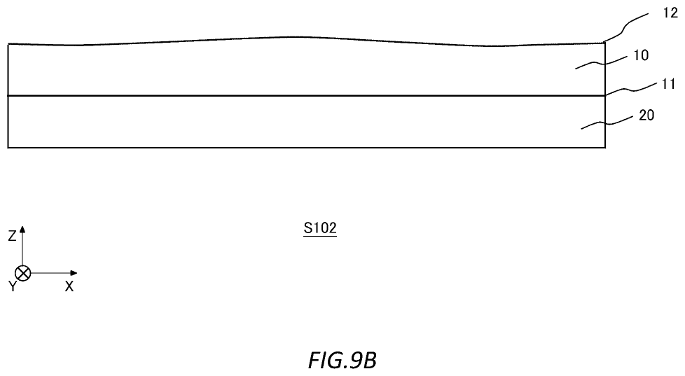

FIG. 9A and FIG. 9B illustrate other examples of the first grinding S102. FIG. 9A illustrates the semiconductor device 100 before grinding, in the first grinding S102. FIG. 9B illustrates the semiconductor device 100 after grinding, in the first grinding S102. In FIG. 9A and FIG. 9B, the shape of the table 120 is changed from FIG. 3A and FIG. 3B.

In the present example, the table 120 used in the first grinding S102 is processed such that the shape of the second surface 12 of the semiconductor substrate 10 after the first grinding S102 is flattened. That is, the shape of the table 120 in the present example may be the same as the shape of the table 140 in FIG. 6. Specifically, regarding the table 120, in a portion 124 overlapping with the first surface 11 of the semiconductor substrate 10, a height of the upper surface 121 monotonously decreases from a center part 126 of the portion 124 to an end part 128 of the portion 124. The height of the upper surface 121 of the table 120 is the height of the table 120 from the lower surface 123 (reference). That is, a height H2 of the upper surface 121 of the table 120 in the center part 126 of the portion 124 may be the maximum among the height of the upper surface 121 of the table 120 in the portion 124. The center part 126 of the portion 124 is a predetermined portion including the center of the portion 124 in the X axis or the Y axis. The end part 128 is an end portion of the portion 124 in the X axis or the Y axis. By allowing the table 120 to have such shape, the center part 14 of the semiconductor substrate 10 can be made higher as compared to other portions. Accordingly, in the first grinding S102, the center part 14 of the semiconductor substrate 10 can be largely ground as compared to other portions, and the in-plane uniformity of the semiconductor substrate 10 can be improved.

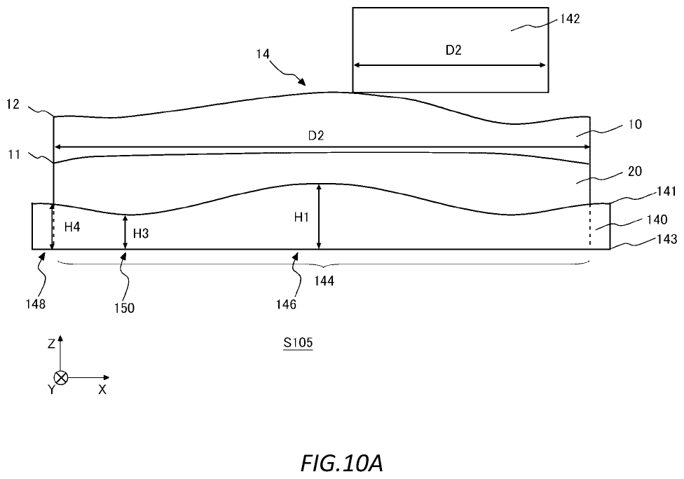

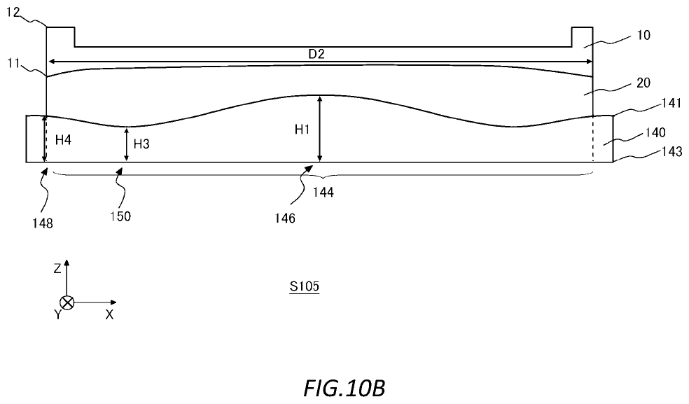

FIG. 10A and FIG. 10B illustrate other examples of the second grinding S105. FIG. 10A illustrates the semiconductor device 100 before grinding, in the second grinding S105. FIG. 10B illustrates the semiconductor device 100 after grinding, in the second grinding S105. In FIG. 10A and FIG. 10B, the shape of the table 140 is changed from FIG. 7A and FIG. 7B.

In the present example, regarding the table 140, in the portion 144 overlapping with the first surface 11 of the semiconductor substrate 10, a valley part 150 is provided between the center part 146 of the portion 144 and the end part 148 of the portion 144. The valley part 150 is a predetermined portion including a portion where the height of the upper surface 141 is lower than the center part 146 and the end part 148. A height H3 of the upper surface 141 of the table 140 in the valley part 150 may be lower than the height H1 of the upper surface 141 of the table 140 in the center part 146. The height H3 of the upper surface 141 of the table 140 in the valley part 150 may be lower than a height H4 of the upper surface 141 of the table 140 in the end part 148. If the semiconductor substrate 10 has the valley part 18 between the center part 14 and the end part 16 as in FIG. 3B, the in-plane uniformity of the semiconductor substrate 10 can be further improved by allowing the table 140 to have such shape.

The height H1 of the upper surface 141 of the table 140 in the center part 146 of the portion 144 may be the highest among the height of the upper surface 141 of the table 140 in the portion 144. By having such configuration, the center part 14 of the semiconductor substrate 10 can be arranged relatively higher as compared to other portions. Accordingly, the center part 14 of the semiconductor substrate 10 can be largely ground as compared to other portions, and the in-plane uniformity of the semiconductor substrate 10 can be improved.

The maximum value of the difference in heights of the upper surface 141 of the table 140 may be 0.005% or less of the diameter D1 of the semiconductor substrate 10. In the present example, the maximum value of the difference in the heights of the table 140 may be a difference between the height H1 of the upper surface 141 of the table 140 in the center part 146 and the height H3 of the upper surface 141 of the table 140 in the valley part 150. That is, if the diameter D1 of the semiconductor substrate 10 is 300 mm, the maximum value of the difference in the heights of the upper surface 141 of the table 140 may be 15 μm or less. In addition, the maximum value of the difference in the heights of the upper surface 141 of the table 140 may be 0.004% or less of the diameter D1 of the semiconductor substrate 10. If the diameter D1 of the semiconductor substrate 10 is 200 mm, the maximum value of the difference in the heights of the upper surface 141 of the table 140 may be 8 μm or less. The point that the TTV is maintained at 2 to 4 μm by setting the grinding depth in the first grinding S102 to 50 μm or more, is described above. However, practically, since there is a variation in machine accuracy, a difference of about double may be caused depending on the processing device performing the first grinding. In addition, even if the maximum value of the difference in the heights of the upper surface 141 of the table 140 has such range, the forward inclination angle of the whetstone 142 may be constant.

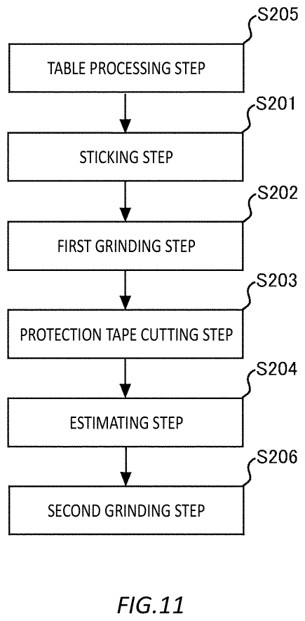

FIG. 11 illustrates another example of the manufacturing method of the semiconductor device 100. In FIG. 11, the manufacturing method of the semiconductor device 100 includes a table processing S205, a sticking S201, a first grinding S202, a protection tape cutting S203, an estimating S204, and a second grinding S206. The manufacturing method of the semiconductor device 100 in FIG. 11 is different from the manufacturing method of the semiconductor device 100 in FIG. 1 on the point that the estimating S204 is provided after the protection tape cutting S203. That is, the table processing S205, the sticking S201, the first grinding S202, the protection tape cutting S203, and the second grinding S206 in FIG. 11 may be the same as the table processing S104, the sticking S101, the first grinding S102, the protection tape cutting S103, and the second grinding S105 in FIG. 1, respectively.

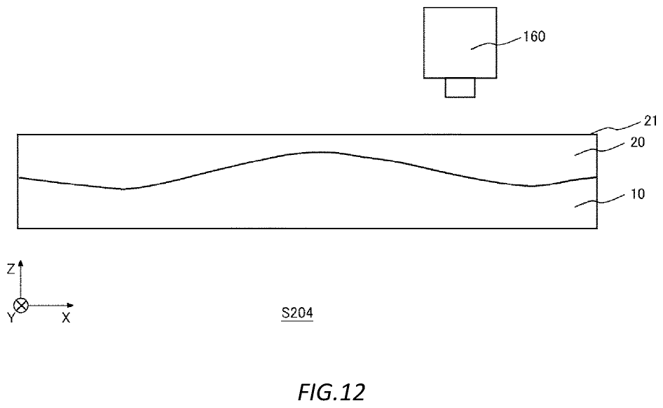

FIG. 12 illustrates an example of the estimating S204. In the estimating S204, deterioration of the flattening tool 132 in the protection tape cutting S203 is estimated. In the present example, since the manufacturing method of the semiconductor device 100 includes the first grinding S202, grinding dust in the first grinding S202 may adhere to the protection tape 20. If the protection tape cutting S203 is performed while the grinding dust is adhered to the protection tape 20, the flattening tool 132 is assumed to be deteriorated. In the present example, since the estimating S204 is provided, deterioration of the flattening tool 132 can be estimated, and a replacement cycle and a maintenance cycle of the flattening tool 132 can be automatically determined. Accordingly, a defect in the protection tape cutting S203 can be suppressed.

In the estimating S204, appearance information on the front surface of the protection tape 20 after the protection tape cutting S203 is acquired, and deterioration of the flattening tool 132 in the protection tape cutting S203 is estimated. In the present example, a device 160 acquires the appearance information on the first surface 21 of the protection tape 20 after the protection tape cutting S203.

The appearance information is, as an example, a reflectivity of the protection tape 20. In the estimating S204, deterioration of the flattening tool 132 may be estimated by measuring a change in the reflectivity of the first surface 21 of the protection tape 20 after the protection tape cutting S203. From the study by the inventor of the present application, it was found that due to deterioration of the flattening tool 132, the reflectivity of a visible light tends to monotonously decrease in the first surface 21 of the protection tape 20 after the protection tape cutting S203. Thus, a certain threshold may be set for the reflectivity, and the estimating S204 may be a step for performing comparison between the reflectivity and the threshold.

In addition, the appearance information is, as an example, image information of the protection tape 20. In this case, the device 160 may include a camera. The device 160 may perform an image analysis on the first surface 21 of the protection tape 20. The device 160 may analyze an image contrast in the image analysis of the first surface 21 of the protection tape 20. The device 160 may perform the image analysis and detect the density of grinding marks. That is, in the estimating S204, the density of the grinding marks on the first surface 21 of the protection tape 20 after the protection tape cutting S203 may be measured, and deterioration of the flattening tool 132 may be estimated. From the study of the inventor of the present application, it was found that the density of the grinding marks tends to monotonously increase due to deterioration of the flattening tool 132. Thus, a certain threshold may be set for the density of the grinding marks, and the estimating S204 may be a step for performing comparison between the density of the grinding marks and the threshold.

It should be noted that, although the estimating S204 is performed after the protection tape cutting S203 in the present example, the estimating S204 may be performed in the middle of the protection tape cutting S203. By performing the estimating S204 in the middle of the protection tape cutting S203, deterioration of the flattening tool 132 in the middle of flattening can be estimated.

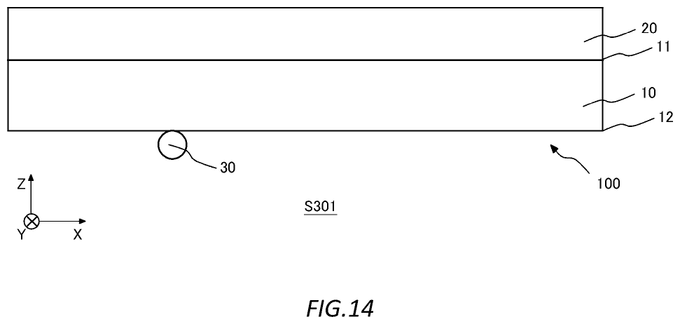

FIG. 13 illustrates a comparative example of the manufacturing method of the semiconductor device 100. The manufacturing method of the semiconductor device 100 in FIG. 13 includes a sticking S301, a protection tape cutting S302, and a substrate grinding S303. Hereinafter, each step will be described in FIG. 14 to FIG. 16C.

FIG. 14 illustrates an example of the sticking S301. The sticking S301 in FIG. 14 may be the same as the sticking S201 in FIG. 2. Also in the present example, the foreign substance 30 is adhered to the second surface 12 of the semiconductor substrate 10.

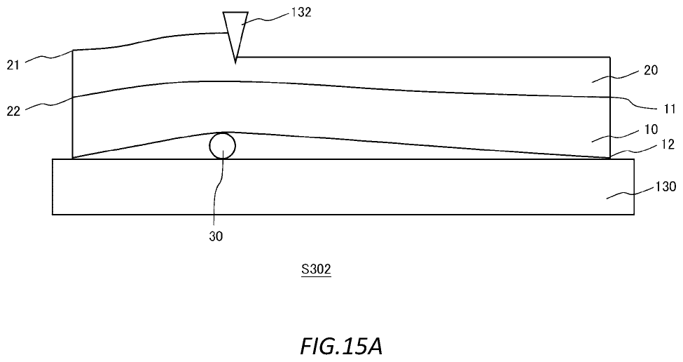

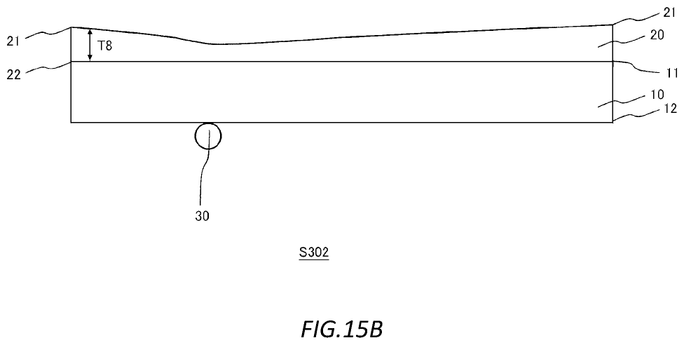

FIG. 15A and FIG. 15B illustrate examples of the protection tape cutting S302. FIG. 15A illustrates the protection tape 20 in the middle of flattening, in the protection tape cutting S302. FIG. 15B illustrates the protection tape 20 after flattening, in the protection tape cutting S302. As in the case of the protection tape cutting S103 in FIG. 5A and FIG. 5B, the protection tape 20 is flattened in the protection tape cutting S302.

In the present example, the foreign substance 30 remains adhered to the second surface 12 of the semiconductor substrate 10. Accordingly, the semiconductor substrate 10 is supported by the table 130 while a portion overlapping with the foreign substance 30 being raised. If the protection tape 20 is flattened in this state, as shown in FIG. 15B, a thickness T8 of the protection tape 20 does not become constant. The thickness T8 of the protection tape 20 is a difference between the height of the first surface 21 of the protection tape 20 and the height of the second surface 22 of the protection tape 20. The protection tape 20 is processed such that it becomes concave near the portion where the foreign substance 30 is adhered.

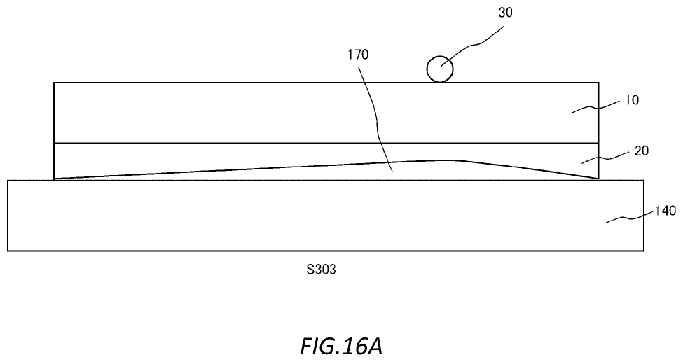

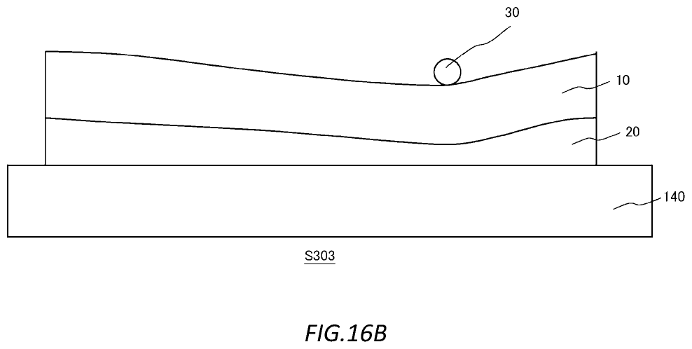

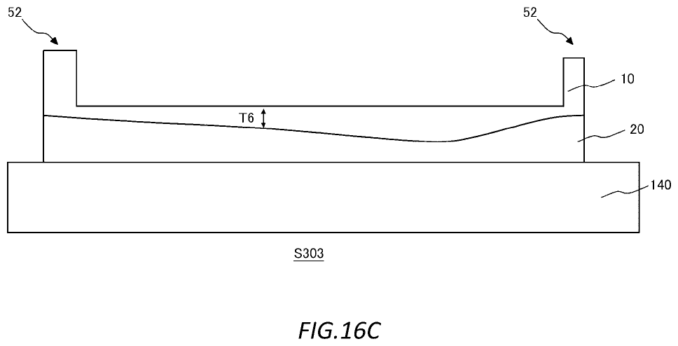

FIG. 16A, FIG. 16B, and FIG. 16C illustrate examples of the substrate grinding S303. FIG. 16A illustrates the semiconductor device 100 before attachment to the table 140, in the substrate grinding S303. FIG. 16B illustrates the semiconductor device 100 after attachment to the table 140, in the substrate grinding S303. FIG. 16C illustrates the semiconductor device 100 after grinding, in the substrate grinding S303.

In FIG. 16A, before attachment to the table 140, a space 170 exists between the table 140 and the protection tape 20. In FIG. 16B, after attachment to the table 140, since the protection tape 20 is attached to the space 170, the semiconductor substrate 10 is also retained such that the portion overlapping with the foreign substance 30 becomes concave. If the semiconductor substrate 10 is ground in this state, as shown in FIG. 16C, the thickness T6 of the semiconductor substrate 10 excluding the convex part 52 does not become constant.

The manufacturing method of the semiconductor device 100 in FIG. 1 includes the first grinding S102. Accordingly, the foreign substance 30 adhered to the second surface 12 of the semiconductor substrate 10 can be removed. The in-plane uniformity of the semiconductor substrate 10 can be improved as compared to the manufacturing method of the semiconductor device 100 in FIG. 13.

FIG. 17 illustrates a forward inclination angle θ1. In FIG. 17, the first grinding S102 in a YZ plane is shown. The lower surface of the whetstone 122 is arranged to have the forward inclination angle θ1 with respect to the Y axis direction. In addition, also in the second grinding S105, the lower surface of the whetstone 142 is arranged to have a forward inclination angle with respect to the Y axis direction. The forward inclination angle of the whetstone 142 in the second grinding S105 is denoted by θ2 (not shown).

The forward inclination angle θ2 of the whetstone 142 in the second grinding S105 may be smaller than the forward inclination angle θ1 of the whetstone 122 in the first grinding S102. In addition, the forward inclination angle θ2 of the whetstone 142 in the second grinding S105 may be the same as the forward inclination angle θ1 of the whetstone 122 in the first grinding S102. The forward inclination angle θ2 of the whetstone 142 in the second grinding S105 may be larger than the forward inclination angle θ1 of the whetstone 122 in the first grinding S102.

While the embodiments of the present invention have been described, the technical scope of the present invention is not limited to the above-described embodiments. It is apparent to persons skilled in the art that various alterations or improvements can be added to the above-described embodiments. It is also apparent from the scope of the claims that the embodiments added with such alterations or improvements can be included in the technical scope of the present invention.

What is claimed is:

1. A manufacturing method of a semiconductor device comprising a semiconductor substrate, the manufacturing method of the semiconductor device comprising:
sticking a protection tape on a first surface of the semiconductor substrate;
first grinding by supporting the protection tape and grinding a second surface of the semiconductor substrate that is a surface on an opposite side of the first surface;
cutting the protection tape by supporting the second surface of the semiconductor substrate and flattening the protection tape; and
second grinding by supporting the protection tape and grinding the second surface of the semiconductor substrate.

2. The manufacturing method of the semiconductor device according to claim 1, wherein
in the second grinding, in order to leave a convex part in an outer circumference of the semiconductor substrate, an inside of the convex part is ground.

3. The manufacturing method of the semiconductor device according to claim 1, further comprising
processing, based on an expected shape of the second surface of the semiconductor substrate after the first grinding, a table for supporting the first surface of the semiconductor substrate in the second grinding.

4. The manufacturing method of the semiconductor device according to claim 1, wherein
in the second grinding, a table for supporting the first surface of the semiconductor substrate has, in a portion overlapping with the first surface of the semiconductor substrate, a valley part between a center part of the portion and an end part of the portion.

5. The manufacturing method of the semiconductor device according to claim 4, wherein
a height of an upper surface of the table in the center part is the highest in the portion.

6. The manufacturing method of the semiconductor device according to claim 4, wherein
a height of an upper surface of the table in the valley part is lower than a height of the upper surface of the table in the end part.

7. The manufacturing method of the semiconductor device according to claim 1, wherein
in the second grinding, regarding a table for supporting the first surface of the semiconductor substrate, in a portion overlapping with the first surface of the semiconductor substrate, a height of an upper surface monotonously decreases from a center part of the portion to an end part of the portion.

8. The manufacturing method of the semiconductor device according to claim 3, wherein
a maximum value of a difference in heights of the table is 0.004% or less of a diameter of the semiconductor substrate.

9. The manufacturing method of the semiconductor device according to claim 1, wherein
in the first grinding, regarding a table for supporting the first surface of the semiconductor substrate, in a portion overlapping with the first surface of the semiconductor substrate, a height of an upper surface monotonously decreases from a center part of the portion to an end part of the portion.

10. The manufacturing method of the semiconductor device according to claim 1, wherein
a grinding depth in the first grinding is smaller than a grinding depth in the second grinding.

11. The manufacturing method of the semiconductor device according to claim 1, further comprising
estimating, by acquiring appearance information on a front surface of the protection tape after the cutting of the protection tape, deterioration of a flattening tool in the cutting the protection tape from the appearance information.

12. The manufacturing method of the semiconductor device according to claim 11, wherein
the appearance information is a reflectivity of the protection tape.

13. The manufacturing method of the semiconductor device according to claim 11, wherein
the appearance information is image information of the protection tape.

14. The manufacturing method of the semiconductor device according to claim 2, further comprising
processing, based on an expected shape of the second surface of the semiconductor substrate after the first grinding, a table for supporting the first surface of the semiconductor substrate in the second grinding.

15. The manufacturing method of the semiconductor device according to claim 2, wherein
in the second grinding, a table for supporting the first surface of the semiconductor substrate has, in a portion overlapping with the first surface of the semiconductor substrate, a valley part between a center part of the portion and an end part of the portion.

16. The manufacturing method of the semiconductor device according to claim 3, wherein
in the second grinding, a table for supporting the first surface of the semiconductor substrate has, in a portion overlapping with the first surface of the semiconductor substrate, a valley part between a center part of the portion and an end part of the portion.

17. The manufacturing method of the semiconductor device according to claim 5, wherein
a height of the upper surface of the table in the valley part is lower than a height of the upper surface of the table in the end part.

18. The manufacturing method of the semiconductor device according to claim 2, wherein
in the second grinding, regarding a table for supporting the first surface of the semiconductor substrate, in a portion overlapping with the first surface of the semiconductor substrate, a height of an upper surface monotonously decreases from a center part of the portion to an end part of the portion.

19. The manufacturing method of the semiconductor device according to claim 3, wherein
in the second grinding, regarding a table for supporting the first surface of the semiconductor substrate, in a portion overlapping with the first surface of the semiconductor substrate, a height of an upper surface monotonously decreases from a center part of the portion to an end part of the portion.

20. The manufacturing method of the semiconductor device according to claim 4, wherein
a maximum value of a difference in heights of the table is 0.004% or less of a diameter of the semiconductor substrate.
